(19) United States
(12) Patent Application Publication
(10) Pub. No.: US 2026/0262165 A1
(43) Pub. Date: Sep. 3, 2026

(54) MEMORY MODULES AND SOCKETS

(71) Applicant: Intel Products IP LLC, Santa Clara, CA (US)

(72) Inventors: Xiang Li, Portland, OR (US); Todd Hinck, Arlington, VA (US); George Vergis, Portland, OR (US); James McCall, Portland, OR (US)

(73) Assignee: Intel Products IP LLC, Santa Clara, CA (US)

(21) Appl. No.: 19/652,822

(22) Filed: Apr. 20, 2026

Related U.S. Application Data
(63) Continuation of application No. 19/000,098, filed on Dec. 23, 2024.

(51) Int. Cl. H05K 1/11

(52) U.S. Cl. CPC H05K 1/117; H05K 2201/09063; H05K 2201/09409; H05K 2201/10159

(57) ABSTRACT

Memory modules and sockets are disclosed. An example memory module comprises a circuit board, a first row of connection pins disposed along an edge of the circuit board, and a second row of pins disposed adjacent to the first row of pins and further from the edge than the first row of pins.

### CLAIM TO PRIORITY

This Application is a continuation of and claims the benefit of and priority to U.S. application Ser. No. 19/000,098, entitled MEMORY MODULES AND SOCKETS, by Xiang Li, et al., filed Dec. 23, 2024, the entire contents of which are incorporated herein by reference.

### BACKGROUND

Memory modules are often coupled to a circuit board (e.g., motherboard) via a removable socket. For example, a common type of memory module is a dual in-line memory module (DIMM) utilized in computers. One particular type of DIMM is the dual data rate 5 (DDR5) U/R DIMM, which is inserted into a socket that includes finger contacts that connect to pins disposed on an edge of the card. The connector is coupled (e.g., soldered) to a motherboard. An example DDR5 memory module is 133.35 millimeters (mm) wide and 31.25 mm tall and includes a single row of 288 pins along a button edge that couples with a connector includes 288 fingers that couple to the pins.

### BRIEF DESCRIPTION OF THE DRAWINGS

FIG. 1A is a schematic diagram of a first side of an example reduced width DIMM.

FIG. 1B is a schematic diagram of a second side of the example reduced width DIMM.

FIG. 2A is a schematic diagram of a side view of an example socket.

FIG. 2B is a schematic diagram of a top view of the example socket.

FIG. 3 is a schematic diagram illustrating the insertion of the example DIMM into the socket frame.

FIG. 4 is a schematic diagram of an example implementation of a structure for the connector pins of the socket engaging the DIMM.

FIG. 5 is a diagram illustrating an example pinout to be utilized with the example DIMM.

FIGS. 6A, 6B, and 6C are schematic diagrams illustrating the installation and extraction of the DIMM into the socket frame.

FIG. 7 is a schematic diagram illustrating an example motherboard with a memory controller, and a plurality of the sockets frames.

FIG. 8 is a schematic diagram illustrating connector footprint and routing.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Example memory modules disclosed herein have a reduced width (e.g., approximately half) as compared with, for example, full width DDR5 memory modules. For example, a memory module as disclosed herein may have a width of 71.4 mm as compared with an example full DIMM width of 133.35 mm. The reduced width allows DIMMs implemented as disclosed herein to be placed side-by-side within the same space of a single full-width DIMM. In addition, by utilizing two smaller DIMMs instead of one full-width DIMM, a larger number of memory channels may be provided on a circuit board (e.g., motherboard) in the same area that previously included a single full-width DIMM. For example, the trace routing between a memory controller and the DIMM may be shorter (e.g., as compared with two full-width DIMMs placed in series where one DIMM is further from the memory controller than a second DIMM. In some examples, the DIMMs as disclosed herein may be single channel DIMMS (e.g., as opposed to 1.5 or 2 channel DIMMS), which allows for swapping out one DIMM rather than 2 or more DIMMS if there is an issue. In some examples, the DIMMs disclosed herein may implement dynamic random access memory (DRAM) for a graphics processing unit memory (e.g., DDR6 memory).

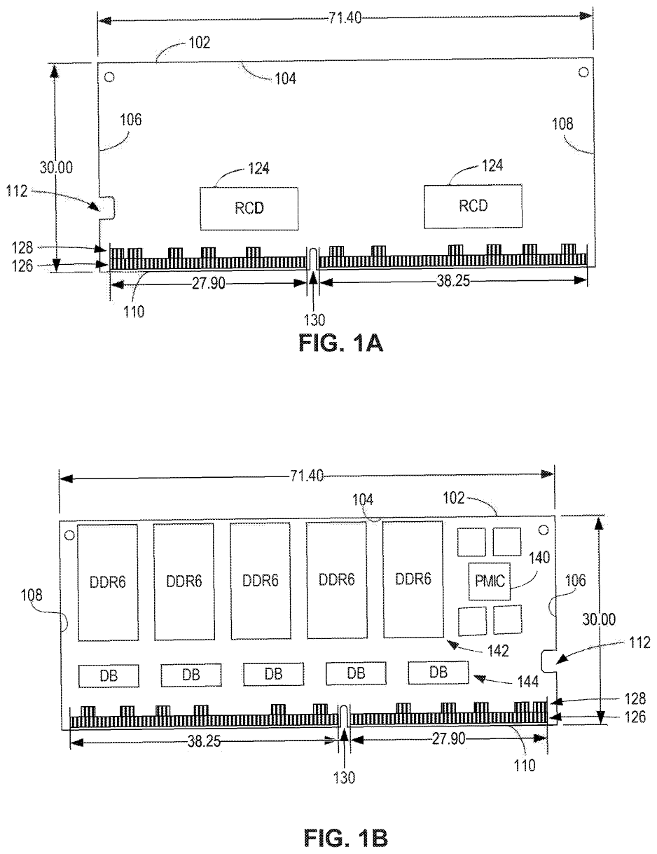

FIG. 1A is a schematic diagram of a first side (e.g., a back) of an example reduced width DIMM 102 as disclosed herein. FIG. 1B is a schematic diagram of a second side (e.g., a front) of the example reduced width DIMM 102.

The example DIMM 102 includes a top edge 104, a first side edge 106, a second side edge 108, and a bottom edge 110. The use of the descriptions top, bottom, and side are used for clarity of description and are not intended to limit the orientations in which the DIMM 102 may be utilized. The example DIMM 102 has a width of 71.40 mm (length of top edge 104 and bottom edge 110) and a height of 30.00 mm (length of first side edge 106 and second side edge 108). Alternatively, the DIMM 102 may be implemented with other dimensions such as, for example, a width less than 75 mm, a height larger than 30 mm, a height less than 30 mm, etc. While the DIMM 102 is described as a reduced width DIMM, the DIMM 102 could be implemented as a full-width DIMM (e.g., a width of 71.4 mm) that includes one or more of the other characteristics of the DIMM 102 described herein.

The example DIMM 102 includes a notch 112 in the first edge 106. The example notch 112 is positioned to allow a latch of a socket to engage the notch 112 to releasably secure the DIMM 102 into a socket. While the example DIMM 102 includes a single notch 112, one or more additional notches 112 may be included (e.g., a notch in the second side edge 108.

The first side of the example DIMM 102 includes example memory components for illustration purposes. For example, the DIMM 102 includes two registered clock drivers 124. Alternatively, the first side of the DIMM 102 may include any number and type of components (e.g., integrated circuits, resistors, capacitors, inductors, diodes, transistors, power management circuit, etc.).

The first side of the example DIMM 102 includes a first row of pins 126 that are adjacent to the bottom edge 110 and a second row of pins 128 that are separated from the bottom edge 110 by the first row of pins 126. According to the illustrated example, the first row of pins 126 includes 298 pins and the second row of pins includes 107 pins. Alternatively, any number of pins may be included in an implementation of the DIMM 102. For example, the second row of pins 128 may include the same number of pins as the first row of pins 126. While a DIMM 102 may include a particular number of pins, not every pin needs to be connected to components of the DIMM 102. The example DIMM 102 includes has a pin pitch of 0.42 mm. Alternatively, other implementations may utilize a larger or smaller pin pitch.

The example DIMM 102 includes a key slot 130 cut into the bottom edge 110, which is utilized for aligning the DIMM 102 in a socket. According to the illustrated example, the key slot 130 is not centered along the bottom edge 110 so that the DIMM 102 can only be inserted into a socket in one orientation. While the DIMM 102 includes a single key slot 130, other implementations may include any number of key slots that correspond to a socket (e.g., zero key slots, 2 key slots, etc.) and the key slot(s) may be positioned in any position. The example key slot 130 separates a first side of the pins 126,128 from a second side of the pins 126,128. For example, the first side of the pins spans 27.90 mm and the second side of the pins 126,128 spans 38.25 mm. Alternatively, the pins may be positioned further from the bottom edge 110 and/or the key slot may be reduced in size to that the pins 126,128 are not separated by the key slot 130 and/or the dimensions of sides of the pins 126, 128 may be any other dimensions.

Turning to the second side of the DIMM 102 illustrated in FIG. 1B, the example DIMM includes additional memory components for illustrative purposes. In particular, the DIMM 102 includes a power management integrated circuit (PMIC) 140, a plurality of memory chips 142 (e.g., DDR6 memory chips), and a plurality of data buffers 144. Alternatively, the second side of the DIMM 102 may include any number and type of components (e.g., integrated circuits, resistors, capacitors, inductors, diodes, transistors, power management circuit, etc.).

The second side of the example DIMM 102 includes a first row of pins 146 that are adjacent to the bottom edge 110 and a second row of pins 148 that are separated from the bottom edge 110 by the first row of pins 146. According to the illustrated example, the first row of pins 146 includes 298 pins and the second row of pins 148 includes 107 pins. Alternatively, any number of pins may be included in an implementation of the DIMM 102. For example, the second row of pins 128 may include the same number of pins as the first row of pins 146. While a DIMM 102 may include a particular number of pins, not every pin needs to be connected to components of the DIMM 102.

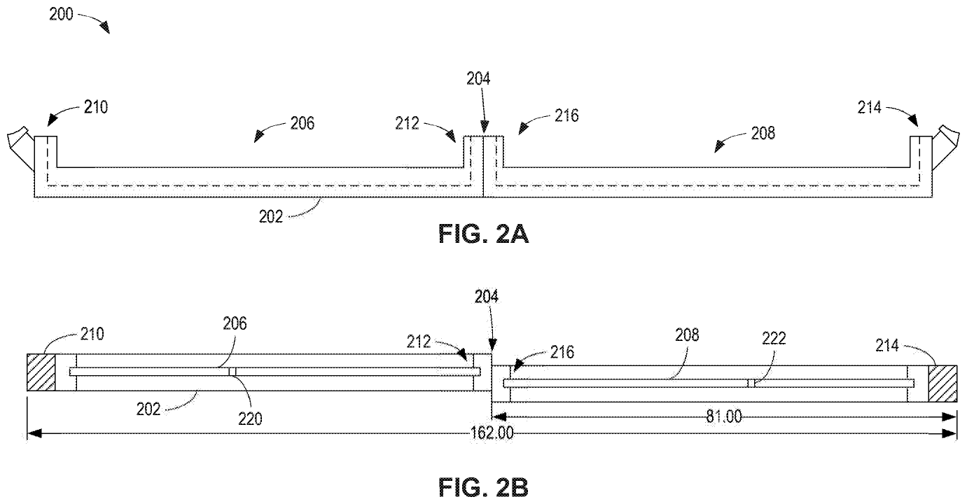

FIG. 2A is a schematic diagram of a side view of an example socket 200. FIG. 2B is a schematic diagram of a top view of the example socket 200. The example socket 200 is structured to receive and hold two of the example DIMMs 102 and to communicatively couple the DIMMs 102 to another component such as a motherboard or other type of circuit board.

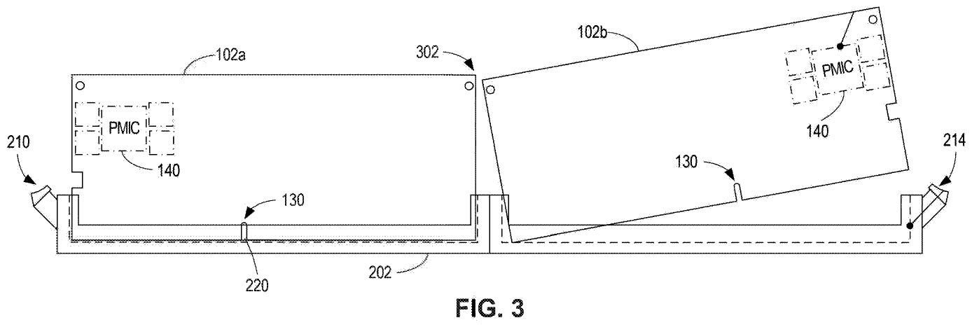

The example socket 200 includes a socket frame 202 that is formed from molded plastic. Alternatively, the socket frame 202 may be made of one or more other materials that can provide a structure for holding the DIMM 102. According to the illustrated example, the socket frame 202 is a single molded plastic that is structured to hold two DIMMs 102. The example socket 200 is 162 mm wide. Alternatively, the socket frame 202 may be separated into two 81 mm socket frames 202 at the dividing line 204 and the socket frame 202 may be structured to hold a single DIMM 102. For example, two socket frames 202 may be located side by side to hold two DIMMs 102. The example socket frame 202 includes an offset layout when viewed from the top to allow two DIMMs 102 to be inserted into the socket 200 at an angle without making contact with each other (e.g., as demonstrated in FIG. 3). Alternatively, the distance between the DIMMs 102 inserted into the socket may be large enough that the DIMMs 102 do not interfere and the socket frame may not include the offset.

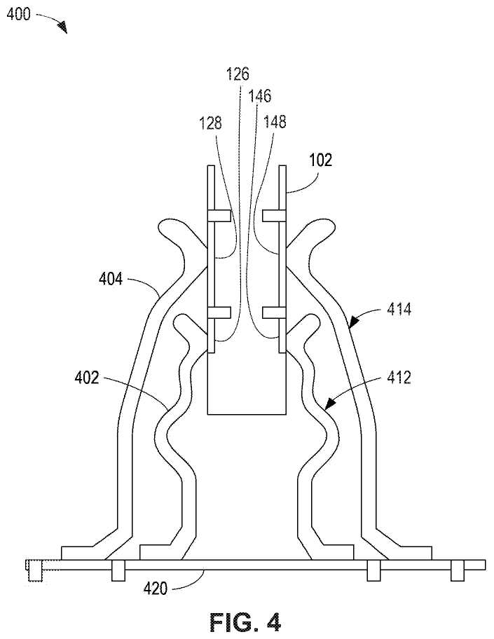

The example socket 200 includes a first slot 206 to hold a first DIMM 102 and a second slot 208 to hold a second DIMM 102. For example, the slots 206, 208 may be dimensioned to match a thickness of the DIMM 102 so that the DIMM 102 may be inserted into the slots 206, 208. The slots 206, 208 include a plurality of connector pins (not shown) that engage with the pins of the DIMM 102. An example implementation of the connector pins is described in conjunction with FIG. 4.

The example socket 200 includes a first latch 210, a first engagement 212, a second latch 214, and a second engagement 216. According to the illustrated example, only a single latch is utilized for each slot 206, 208 to enable the slots 206, 208 to be close together, which reduces the space taken by the socket 200 (e.g., the amount of space taken on a motherboard). Alternatively, two latches may be utilized for some or all of the slots 206, 208. The example first engagement 212 and the second engagement 216 are implemented by a spring or resilient member that engages the DIMM 102 to secure the DIMM 102 in the slot 206, 208.

The example first slot 206 includes an example key 220 and the example second slot 208 includes an example key 222. The keys 220, 222 engage with the key slot 130 of the DIMM 102. For example, when the key 220, 222 is located off-center in the slot 206, 208, the DIMM 102 can only be inserted in one direction ensuring that the DIMM 102 is not inserted backwards.

FIG. 3 is a schematic diagram illustrating the insertion of the example DIMM 102 into the socket frame 202. As illustrated in FIG. 3, as a DIMM 102 is being inserted into the socket frame 202 while another DIMM 102 is already inserted, the angled insertion would result in a collision between the two DIMMs 102 at area 302. However, because the socket frame 202 includes the first slot 206 laterally offset from the second slot 208, the DIMMs 102 can be inserted without collision.

FIG. 4 is a schematic diagram of an example implementation of a structure 400 for the connector pins of the socket 200 engaging the DIMM 102. The example structure 400 includes a first connector pin 402, a second connector pin 404, a third connector pin 412, and a fourth connector pin 414. The example first connector pin 402 and example third connector pin 412 are shorter than the example second connector pin 404 and the example fourth connector pin 414. The first connector pin 402 is to connect with the first row of pins 126 and the second connector pin 404 is to connect with the second row of pins 128. The third connector pin 412 is to connect with the first row of pins 146 and the fourth connector pin 414 is to connect with the second row of pins 148.

The example slots 206, 208 include a plurality of the structures 400. According to the illustrated example, the slots 206, 208 include 298 of the structures 400 to communicatively couple the socket 200 with the 298 pins of the DIMM 102. Alternatively, any number of the structures 400 may be included. Further, while the example structures includes four connector pins, some or all of the structures 400 may include fewer than four pins (e.g., in positions in which a DIMM 102 may not include all four possible pins (e.g., the shorter connector pins 402, 412 may be excluded in a position in which a DIMM will only include pins in the second rows of pins 128, 148.

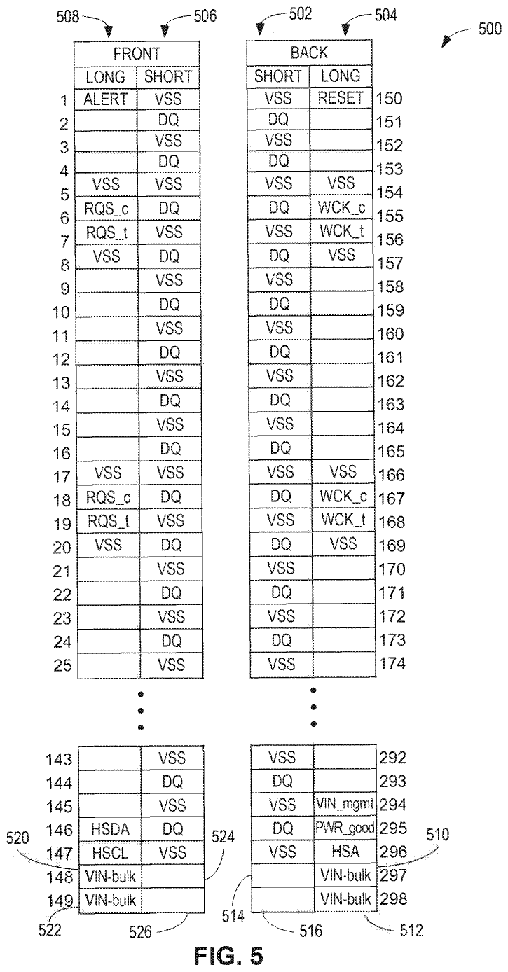

FIG. 5 is a diagram illustrating an example pinout 500 to be utilized with the example DIMM 102. The example pinout 500 includes a first row 502 (e.g., corresponding to the first row of pins 126), a second row 504 (e.g., corresponding to the second row of pins 128), a third row 506 (e.g., corresponding to the first row of pins 146), and a fourth row 508 (e.g., corresponding to the second row of pins 148). While particular functionality is identified in the various pin positions, an implementation of the DIMM 102 may include any functionality and this patent is not limited to particular pin positions.

In the example pinout 500, pin 297 of the second row 504 is a first input voltage pin 510, pin 298 of the second row 504 is a second input voltage pin 512, pin 297 of the first row 502 is intentionally left unconnected 514, pin 298 of the first row 502 is intentionally left unconnected 516. In the example pinout 500, pin 148 of the fourth row 508 is a third input voltage pin 520, pin 149 of the fourth row 508 is a fourth input voltage pin 522, pin 148 of the third row 506 is intentionally left unconnected 524, pin 149 of the third row 506 is intentionally left unconnected 526. By including the unconnected pins next to and below the voltage pins 510, 512, 520, 522, inadvertent connection of corresponding voltage pins of the socket 200 to pins (e.g., data pins) on the DIMM 102 is avoided while the DIMM 102 is being inserted into or removed from the socket 200.

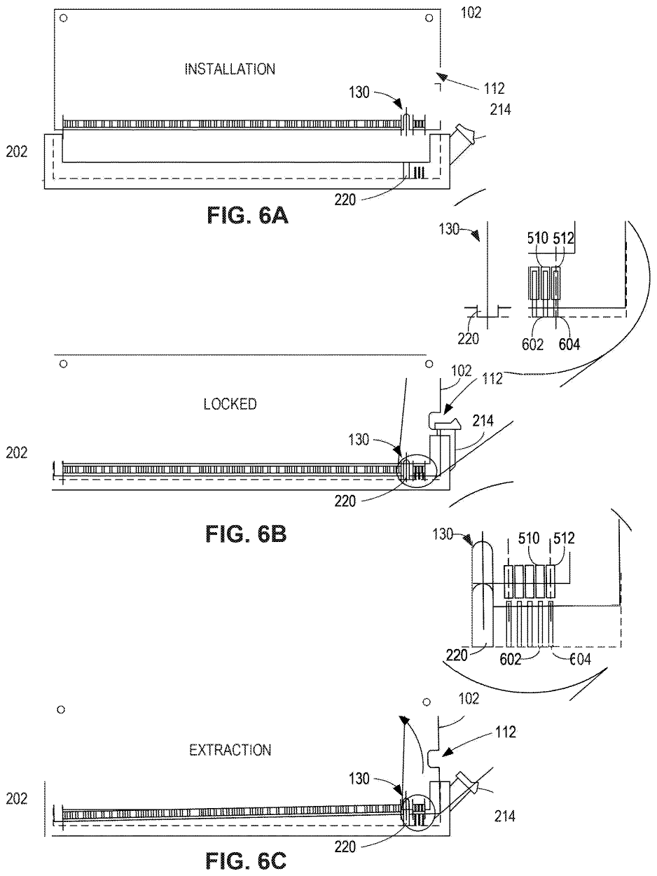

FIGS. 6A, 6B, and 6C are schematic diagrams illustrating the installation and extraction of the DIMM 102 into the socket frame 202. According to the illustrated example, the power pins for the DIMM 102 are the pins closest to the edge of the DIMM 102 (e.g., pins 148, 149, 297, and 298 as shown in FIG. 5). According, when the DIMM 102 is installed in the socket frame 202, example connector pins 602, 604 are coupled to the DIMM 102. When the DIMM 102 is extracted from the socket frame 202 by lifting the side of the DIMM 102 closest to the latch 214, the connector pins 602, 604 are disconnected from the corresponding pins 510, 512 before the other pins of the DIMM 102 are disconnected, which provides protection for the power management integrated circuit 140.

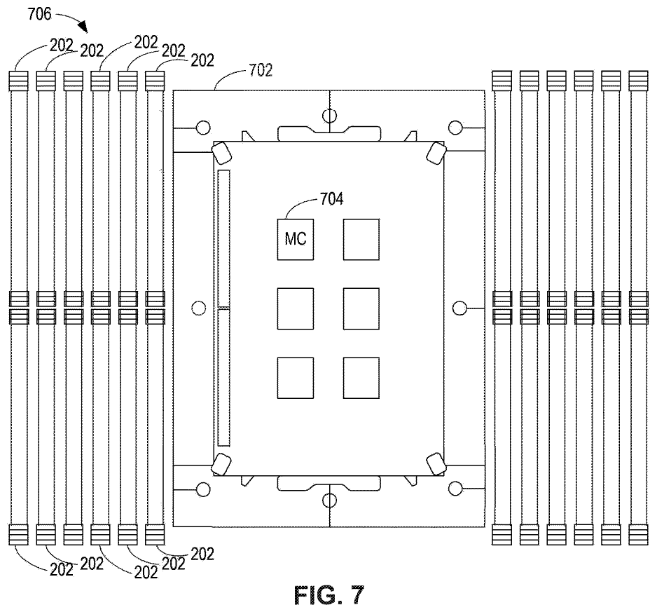

FIG. 7 is a schematic diagram illustrating an example motherboard 702 with a memory controller 704, and a plurality 706 of the sockets frames 202. As shown in FIG. 7, because the socket frames 202 can be placed side by side in approximately the same space that a single full-width DIMM socket would take, twice as many socket frames 202 can be placed. Furthermore, twelve of the example socket frames 202 can be positioned such that the socket frame that is furthest from the memory controller 704 is only the distance of six socket frames 202 away. In contrast, twelve full-width socket frames would be placed in series such that the further socket frame would be the distance of twelve socket frames away. Accordingly, the example socket frames 202 facilitate reduced space utilized by the socket frames 202 and a reduced distance between the memory controller 704 of the socket frames 202.

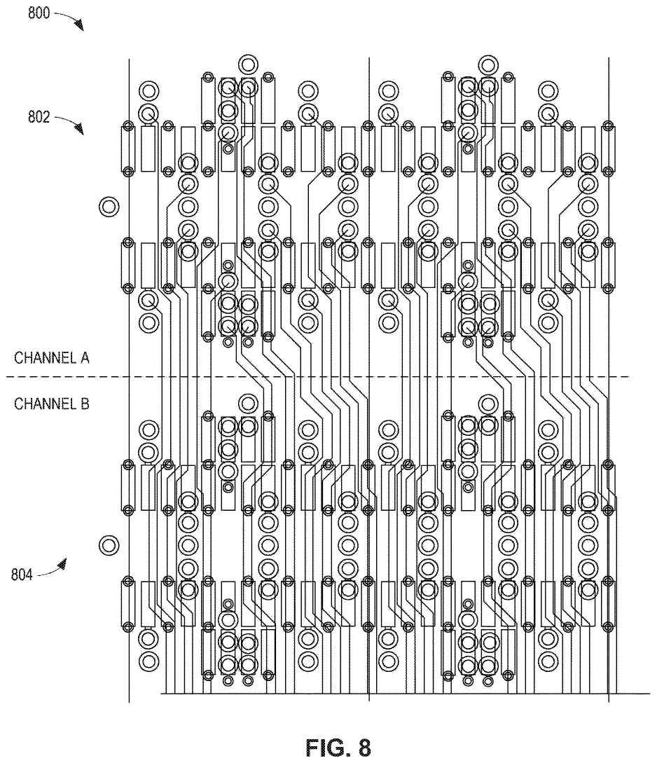

FIG. 8 is a schematic diagram illustrating connector footprint and routing. As illustrated in FIG. 8, when the socket frames 202 are placed side by side, two memory channels can be routed on one layer (e.g., of a motherboard) unlike DDR5 memory that includes one layer for each memory channel. An example layer layout 800 includes a first channel 802 (e.g., coupled to a first socket frame 202) and a second channel 804 (e.g., coupled to a second socket frame 202).

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

Example memory modules and sockets are disclosed herein. Further examples and combinations thereof include the following:

Example 1 includes a memory module comprising a circuit board, a first row of connection pins disposed along an edge of the circuit board, and a second row of pins disposed adjacent to the first row of pins and further from the edge than the first row of pins.

Example 2 includes the memory module of example 1, wherein the circuit board has a width less than 75 millimeters.

Example 3 includes the memory module of any foregoing example, wherein the memory module is a dual in-line memory module (DIMM).

Example 4 includes the memory module of any foregoing example, wherein the first row of pins does not include pins between a subset of the second row of pins and the edge of the circuit board.

Example 5 includes the memory module of example 4, wherein the circuit board includes a key slot between the subset of the second row of pins and remaining pins of the second row of pins.

Example 6 includes the memory module of example 5, wherein the subset of the second row of pins are to couple the memory module to a power source.

Example 7 includes the memory module of example 6, wherein the subset of the second row of pins are the closest pins to a side of the circuit board.

Example 8 includes the memory module of any foregoing example, further including at least one memory chip disposed on the circuit board.

Example 9 includes the memory module of example 8, further including a power management integrated circuit disposed on the circuit board.

Example 10 includes the memory module of any foregoing example, wherein the width of the circuit board is example 71 includes 4 millimeters.

Example 11 includes the memory module of example 10, wherein a height of the circuit board is 30 millimeters.

Example 12 includes the memory module of any foregoing example, wherein the first row of pins includes 298 pins.

Example 13 includes the memory module of example 12, wherein the second row of pins includes 107 pins.

Example 14 includes the memory module of any foregoing example, wherein the first row of pins and the second row of pins have a pitch of example 0 includes 45 millimeters.

Example 15 includes a connector for a memory module comprising a socket to accept a memory module, a first set of connector pins having a first length, and a second set of connector pins having a second length, the first length longer than the second length.

Example 16 includes the connector of example 15, wherein a number of connector pins in the first set of connector pins is less than a number of connector pins in the second set of connector pins.

Example 17 includes the connector of any foregoing example, further comprising a first latch at a first end of the socket.

Example 18 includes the connector of any foregoing example, further comprising a spring connection at a second end of the socket opposite the first end of the socket.

Example 19 includes an apparatus comprising a circuit board a first socket disposed on the circuit board, the first socket having a first set of opposing sides and a second set of opposing sides, wherein a length of the first set of opposing sides is greater than a length of the second set of opposing sides, and a second socket disposed on the circuit board, the second socket having a first dimension and a second dimension, wherein the first dimension is greater than the second dimension, wherein a length of the first set of opposing sides is greater than a length of the second set of opposing sides, wherein the first socket is adjacent the second socket along one of the second sides.

Example 20 includes the apparatus of any foregoing example, wherein the first socket is offset from the second socket.

From the foregoing, it will be appreciated that example memory modules and sockets have been disclosed that have a reduced width that facilitates placement of two sockets side-by-side in approximately the same space as a single full-width socket. Such an arrangement can allow for multiple memory channels to be routed in a single layer on a circuit board (e.g., a motherboard). Disclosed systems, apparatus, articles of manufacture, and methods are accordingly directed to one or more improvement(s) in the operation of a machine such as a computer or other electronic and/or mechanical device.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A computing device comprising:
a dual in-line memory module (DIMM) device coupled to processing circuitry; and
a circuit board having a reduced width and coupled to the DIMM device, wherein the DIMM device includes a key slot formed in a bottom edge of the circuit board, wherein the key slot is not positioned centered along the bottom edge and separating the connection pins into a first side and second side.

2. The computing device of claim 1, further comprising:
a first row of the connection pins disposed along an edge of the circuit board; and
a second row of the connection pins disposed and adjacent to the first row of the connection pins and further from the edge than the first row of the connection pins.

3. The computing device of claim 1, wherein the first row and the second row are placed in an adjacent arrangement to allow at least two reduced width DIMM devices to be placed in a same space of a single full-width DIMM device, wherein the arrangement to increase memory module density and memory channels.

4. The computing device of claim 1, wherein the DIMM device comprises two notches formed in the side edge, and wherein the circuit board having the reduced width less than 75 millimeters.

5. The computing device of claim 1, wherein the DIMM comprises a DDR6 memory device comprising one or more memory chips and a power management integrated circuit (PMIC).

6. The computing device of claim 1, wherein the processing circuitry comprises application processing circuitry or graphics processing circuitry.

7. A memory device comprising:
a dual in-line memory module (DIMM) device; and
a circuit board having a reduced width and coupled to the DIMM device, wherein the DIMM device includes a key slot formed in a bottom edge of the circuit board, wherein the key slot is not positioned centered along the bottom edge and separating the connection pins into a first side and second side.

8. The memory device of claim 7, further comprising:
a first row of the connection pins disposed along an edge of the circuit board; and
a second row of the connection pins disposed and adjacent to the first row of the connection pins and further from the edge than the first row of the connection pins.

9. The memory device of claim 7, wherein the first row and the second row are placed in an adjacent arrangement to allow at least two reduced width DIMM devices to be placed in a same space of a single full-width DIMM device, wherein the arrangement to increase memory module density and memory channels.

10. The memory device of claim 7, wherein the DIMM device comprises two notches formed in the side edge, and wherein the circuit board having the reduced width less than 75 millimeters.

11. The memory device of claim 7, wherein the DIMM comprises a DDR6 memory device comprising one or more memory chips and a power management integrated circuit (PMIC).

12. The memory device of claim 7, wherein the DIMM device is coupled to processing circuitry, wherein the processing circuitry comprises application processing circuitry or graphics processing circuitry.
